(19) United States
(12) Patent Application Publication
(10) Pub. No.: US 2026/0022286 A1
(43) Pub. Date: Jan. 22, 2026

(54) IMMERSION COOLING SYSTEM AND WORKING FLUID THEREOF

(71) Applicant: Taiwan Ruomei Technology Corp., Taipei City (TW)

(72) Inventors: Hou-Yu Lee, Taipei City (TW); Si-Han Lin, Taipei City (TW)

(73) Assignee: Taiwan Ruomei Technology Corp., Taipei City (TW)

(21) Appl. No.: 19/248,563

(22) Filed: Jun. 25, 2025

(30) Foreign Application Priority Data
Jul. 17, 2024 (TW) 113126735

(51) Int. Cl. C09K 5/10; H05K 7/20

(52) U.S. Cl. CPC C09K 5/10; H05K 7/20236

(57) ABSTRACT

An immersion cooling system, including: an enclosure, the enclosure including an inner space; a heating part, disposed in the inner space; and a working fluid, filled in the inner space and having thermal contact with the heating part, to transfer the waste heat from the heating part into the outside of the enclosure. The composition of the working fluid includes: a non-conductive coolant and a plurality of modified boron nitride microparticles. The non-conductive coolant and the modified boron nitride microparticles are mutually dissolved in the working fluid, and a molecular structure of the modified boron nitride microparticles includes organic functional groups.

### CROSS REFERENCE

The present invention claims priority to TW 113126735 filed on Jul. 17, 2024.

### BACKGROUND OF THE INVENTION

### Field of Invention

The present invention relates to an immersion cooling system and a working fluid used in the system, in which the heat transfer efficiency of the immersion cooling system can be enhanced with modified boron nitride microparticles in the working fluid.

### Description of Related Art

Conventional cooling systems often use forced convection for providing sufficient heat transfer capability, to transfer the waste heat generated by the heating parts to the outside of the cooling system. The forced convection method includes, for example, cooling fans to blow the working fluid from a hotter position to a cooler position to deliver the waste heat from the hotter position. Since the aforementioned design needs a forced convection mechanism, which is substantially not economical in terms of energy utilization. In case of the conventional cooling systems relying on the forced convection mechanism, when the forced convection mechanism is unfunctional, the cooling system will fail to operate, causing the entire system to shut down or be unable to operate normally. It may result in severe losses or damage.

### SUMMARY OF THE INVENTION

In view of the aforementioned technical needs, the present invention provides an immersion cooling system and a working fluid therein. The immersion cooling system includes: an enclosure, the enclosure including an inner space; a heating part, disposed in the inner space; and a working fluid, filled in the inner space and having thermal contact with the heating part, to transfer the waste heat from the heating part into the outside of the enclosure. The composition of the working fluid includes: a non-conductive coolant and a plurality of modified boron nitride microparticles. The non-conductive coolant and the modified boron nitride microparticles are mutually dissolved in the working fluid, and a molecular structure of the modified boron nitride microparticles includes organic functional groups.

In one embodiment, the non-conductive coolant includes an unsaturated fluoro-olefin compound, unsaturated fluoro-olefin hydroxyl compound, or unsaturated fluorinated olefin compound.

In one embodiment, the immersion cooling system further includes a passive convection heat transfer mode and a forced convection heat transfer mode, wherein in the passive convection heat transfer mode, the working fluid does not undergo a forced convection during heat transfer operation; in the forced convection heat transfer mode, the working fluid transfers the waste heat through the forced convection during the heat transfer operation.

In one embodiment, each of the modified boron nitride microparticles includes an atomic arrangement of a hexagonal boron nitride lattice (e.g., α-BN) or a cubic boron nitride lattice (e.g., β-BN, CBN, etc.). In the passive convection heat transfer mode and the forced convective heat transfer mode, a lattice vibration effect of the modified boron nitride microparticles dissolved in the working fluid, enhances the thermal conductivity of the working fluid, to exhibit a higher heat transfer efficiency compared to the non-conductive coolant.

In one embodiment, the modified boron nitride microparticles are not in a suspended status in the working fluid. That is, the modified boron nitride microparticles are dissolved in the working fluid.

In one embodiment, the particle size of the modified boron nitride microparticles is preferably in the range of 0.01 μm to 5 μm.

In one embodiment, the preferred concentration of the modified boron nitride microparticles in the working fluid ranges from 100 PPM to 10,000 PPM.

In one embodiment, an organic functional group in the molecular structure of the modified boron nitride microparticles, includes a hydroxyl group.

According to one perspective, the present invention provides a working fluid used in the immersion cooling system. The working fluid includes an unsaturated fluoro-olefin compound, unsaturated fluoro-olefin hydroxyl compound, or unsaturated fluorinated olefin compound; and a plurality of modified boron nitride microparticles, wherein the unsaturated fluoro-olefin compound (or unsaturated fluorinated olefin compound) and the modified boron nitride microparticles can be mutually dissolved in the working fluid. The modified boron nitride microparticles, which include an atomic arrangement of a hexagonal boron nitride lattice or a cubic boron nitride lattice, to enhance the thermal conductivity of the working fluid to exhibit a higher thermal conductivity compared to the unsaturated fluoro-olefin compound, unsaturated fluoro-olefin hydroxyl compound, or unsaturated fluorinated olefin compound, due to a lattice vibration effect of the modified boron nitride microparticles, (alternatively, and further due to a combination of the modified boron nitride microparticles and the unsaturated fluoro-olefin compound, unsaturated fluoro-olefin hydroxyl compound, or unsaturated fluorinated olefin compound).

The objectives, technical details, features, and benefits of the present invention can be better understood with regard to the detailed description of the embodiments below, with reference to the associated drawings.

### BRIEF DESCRIPTION OF THE DRAWINGS

FIG. 1 shows a schematic diagram of the immersion cooling system according to one embodiment of the present invention.

FIG. 2 shows a schematic diagram of the modified boron nitride microparticles according to one embodiment of the present invention.

FIG. 3 shows a schematic drawing of a schematic diagram of the immersion cooling system according to one embodiment of the present invention.

### DESCRIPTION OF THE PREFERRED EMBODIMENTS

The objectives, technical details, features, and effects of the present invention can be better understood regarding the detailed description of the embodiments below, with reference to the associated drawings. The technical wordings/terms in this specification are based on a customary understanding of the art. In this specification, the interpretations of these wordings/terms are preferentially based on the description or the definition in this specification. Each embodiment of the present invention includes at least one technical feature. To the extent possible, a person having ordinary knowledge in the art may, as needed, select, combine, or modify some or all of the technical features in any one of the embodiments, within the spirit and scope of the present invention.

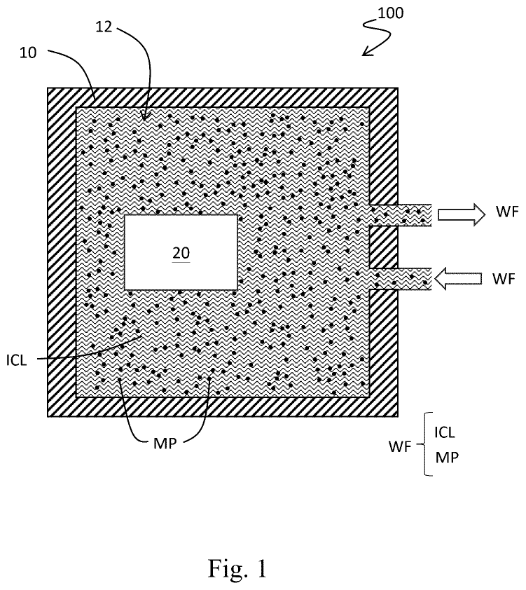

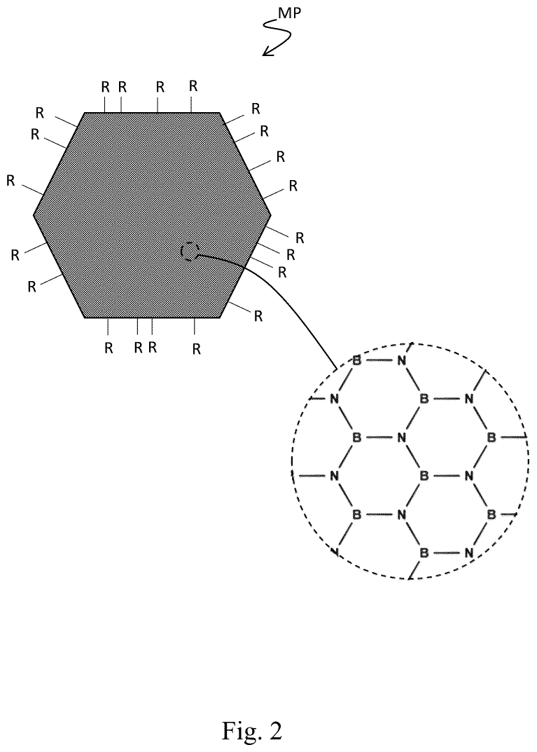

As shown in FIG. 1, the present invention provides an immersion cooling system and a working fluid in the system, wherein the working fluid of the present invention has an enhanced heat transfer capability, compared to conventional working fluids. The immersion cooling system 100 includes: an enclosure 10, including an inner space 12 (the inner space 12 is filled with a working fluid WF as shown in the FIG. 1, basically the inner space 12 is the space surrounded by inner walls of the enclosure 10); a heating part 20 (the shape and the disposition of the heating part 20 in the FIG. 1 are only illustrative, and the heating part 20 may be in various shapes and positions according to its application purpose), located in the inner space 12; a working fluid WF, filled in the inner space 12, including a thermal contact with the heating part 20, to transfer the waste heat from the heating part 20 into the outside of the enclosure 10 (on the right side of the FIG. 1, the working fluid WF leaving the inner space 12 for transferring the waste heat to the outside of the enclosure 10, and then the cooled working fluid WF after transferring the waste heat is returned to the inner space 12). The composition of the working fluid WF includes a non-conductive coolant ICL (illustrated in the FIG. 1 in a wavy form) and a plurality of modified boron nitride microparticles MP (illustrated in the figure by black dots, wherein the modified boron nitride microparticles MP are uniformly dissolved in the working fluid WF). Therein, the non-conductive coolant ICL includes a fluorocarbon compound, and the molecular structure of the modified boron nitride microparticles MP includes an organic functional group R (FIG. 2). With the interaction between the fluorocarbon compound and the organic functional group R, the non-conductive coolant ICL and the modified boron nitride microparticles MP dissolve in each other in the working fluid WF. The modified boron nitride microparticles MP have an insulation and heat conducting effect. According to the present invention, the combination of the non-conductive coolant ICL and the modified boron nitride microparticles MP, significantly increases the heat transfer capability of the working fluid WF.

In one embodiment, the non-conductive coolant ICL can be a fluorocarbon compound, and the fluorocarbon compound includes an unsaturated fluoro-olefin compound, unsaturated fluoro-olefin hydroxyl compound, or unsaturated fluorinated olefin compound. In another point of view, the non-conductive coolant ICL can be a fluorinated liquid, an electronic grade fluorinated liquid, or a fluorine chemical liquid. The fluorinated liquid, the electronic grade fluorinated liquid, or the fluorine chemical liquid, includes the unsaturated fluoro-olefin compound, unsaturated fluoro-olefin hydroxyl compound, or unsaturated fluorinated olefin compound.

In one embodiment, the immersion cooling system 100 has a passive convection heat transfer mode and a forced convection heat transfer mode. In the passive convection heat transfer mode, the working fluid WF does not conduct the heat transfer with forced convection, for example, the heat transfer in a stationary or natural convection state. In the forced convection heat transfer mode, the working fluid WF essentially conducts heat transfer by forced convection. According to the present invention, even in the stationary state, the working fluid WF still has an excellent heat conduction capability.

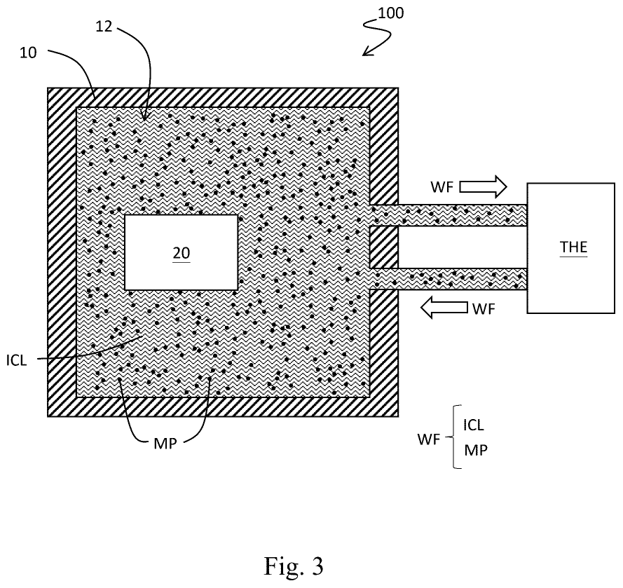

Regarding the detail of the modified boron nitride microparticles MP, in one embodiment as shown in FIG. 2, the modified boron nitride microparticles MP have an atomic arrangement of a hexagonal boron nitride (e.g., α-BN) (please refer to the schematic diagram of the atomic arrangement in the lower-right side of FIG. 2, where the atoms of nitrogen (N) and the boron (B) are linked to each other to form a hexagonal arrangement). Or, the modified boron nitride microparticles MP have an atomic arrangement of a cubic boron nitride (e.g., β-BN, CBN, etc.). These two atomic arrangements correspond to different lattice states. In both of the passive convection heat transfer mode and the forced convective heat transfer mode, the working fluid WF exhibits a thermal conductivity higher than that of the non-conductive coolant ICL due to the lattice vibration effect in the modified boron nitride microparticles MP. This difference can be more obvious in the passive convection heat transfer mode. As shown in FIG. 3, the working fluid WF is transmitted to a heat exchanger THE for heat dissipation. According to the inventor's experiments, it is examined that the heat dissipation efficiency of the immersion cooling computer can be increased by at least about 50% to 65% under a general operating condition, such as operating the immersion cooling computer at room temperature. Based on the same operating condition of the electronic component, the temperature difference (Tb1-Tc1) between the surface temperature (Tb1) of the heating part 20 (contacted to the conventional working fluid WF with the modified boron nitride microparticles MP), and the heat dissipation terminal temperature (Tc1) of the immersion cooling system 100; and the temperature difference (Tb2-Tc2) is obtained between the surface temperature (Tb2) of the heating part 20 (contacted to the conventional working fluid WF without the modified boron nitride microparticles MP), and the heat dissipation terminal (Tc2) of the immersion cooling system 100. The heat dissipation effect can be improved by at least 50% to 65%. In one embodiment, the larger the temperature difference (Tb1-Tc), the greater the heat-carrying capability of the working fluid WF. According to the present invention, (Tb1-Tc1)/(Tb2-Tc2) can reach between 1.5 and 1.65, the improvement is very effective. If the experiment is continued with the concept of the working fluid WF with various configurations of the modified boron nitride microparticles MP, it may have an even higher heat dissipation effect.

In one embodiment, the modified boron nitride microparticles MP are not suspended in the working fluid WF. The modified boron nitride particulates MP can be completely dissolved in the working fluid WF and does not precipitate. In addition, due to the complete solubility and a specific gravity of the modified boron nitride particulates MP being close to (or, fundamentally equivalent to) a specific gravity of the non-conductive coolant ICL, the modified boron nitride particulates MP can be homogeneously dispersed in the working fluid WF. Thus, the lattice vibration effect of the modified boron nitride microparticles MP (e.g., in a microscopic point of view, the lattice vibration effect of the modified boron nitride microparticles MP) can be evenly applied to the working fluid WF. The possibility of the waste heat in the working fluid WF accumulating in any corner of the inner space 12, can be greatly reduced. Furthermore, after a long-term static condition (e.g., during storage, or long-distance transportation), the ratio of the concentration of the modified boron nitride microparticles MP to the non-conductive coolant ICL in each portion of the working fluid WF remains stable, and there is no observable concentration gradient therein, so that the working fluid WF provided by the present invention demonstrates excellent thermal stability and reliability.

In short, to enhance heat transfer efficiency, the modified boron nitride microparticles MP are introduced to be mixed with the non-conductive coolant ICL. The modified boron nitride microparticles MP improve the working fluid WF to have significant benefits of higher thermal performance, operational stability, system design simplification, and easy maintenance.

In one embodiment, the particle size of the modified boron nitride microparticles MP is preferably in the range of 0.01 μm to 5 μm, wherein the particle size includes the range of Nano size levels. The shapes of the modified boron nitride microparticles MP may include long strips, flakes, etc. These shapes can be determined according to the atomic arrangement or the crystallization steps.

In one embodiment, the preferred concentration of the modified boron nitride microparticles MP in the working fluid WF ranges from 100 PPM to 10,000 PPM, and this concentration can be the weight concentration or volume concentration between the modified boron nitride microparticles MP and the working fluid WF.

In one embodiment, an organic functional group in the molecular structure of the modified boron nitride microparticles MP includes a hydroxyl group. Functional groups such as the hydroxyl groups can make modified boron nitride the microparticles MP more easily and stably dispersed in the non-conductive coolant ICL. It can produce hydrogen bonds or dipole interactions with the molecules of the non-conductive coolant ICL, to avoid aggregation and precipitation. Further, functional groups can improve the chemical stability and life of liquids in high-temperature environments.

According to one perspective, the present invention provides a working fluid WF used in an immersion cooling system 100. The working fluid WF includes an unsaturated fluoro-olefin compound (or, unsaturated fluoro-olefin hydroxyl compound, unsaturated fluorinated olefin compound) and a plurality of modified boron nitride microparticles MP. The unsaturated fluoro-olefin compound (or, unsaturated fluoro-olefin hydroxyl compound, unsaturated fluorinated olefin compound) and modified boron nitride microparticles MP are mutually dissolved in the working fluid WF, and the modified boron nitride microparticles MP have an atomic arrangement corresponding to either a hexagonal boron nitride lattice or cubic boron nitride lattice. The working fluid WF can exhibit an enhanced thermal conductivity, due to a lattice vibration effect of the modified boron nitride microparticles.

In another point of view, the aforementioned sentence, “the unsaturated fluoro-olefin compound (or, unsaturated fluoro-olefin hydroxyl compound, unsaturated fluorinated olefin compound) and modified boron nitride microparticles MP are mutually dissolved in the working fluid WF”, can be described as “the unsaturated fluoro-olefin compound (or, unsaturated fluoro-olefin hydroxyl compound, unsaturated fluorinated olefin compound) and modified boron nitride microparticles MP are stably dispersed and well-distributed in the working fluid WF”, or alternatively, “the unsaturated fluoro-olefin compound (or, unsaturated fluoro-olefin hydroxyl compound, unsaturated fluorinated olefin compound) and modified boron nitride microparticles (MP) function as solutes in the working fluid (WF)”. These alternatives specify different natures of this solubility of the unsaturated fluoro-olefin compound (or, unsaturated fluoro-olefin hydroxyl compound, unsaturated fluorinated olefin compound) and modified boron nitride microparticles MP in the working fluid WF.

The above description discloses distinctive features through several embodiments and/or examples for implementing the features of the present invention. The composition and configurations described above are substantially for illustrating the implementations of the present invention. These descriptions are not intended to limit the scope of the present invention. Further, repeated reference symbols or markings may appear in some embodiments for illustrative clarification purposes. Such repetition does not necessarily imply any necessary connection between the described embodiments or configurations.

The present invention has been disclosed with reference to the above embodiments, which are not intended to limit the spirit and scope of the present invention. A person skilled in the art to which the present disclosure pertains may make various modifications and adjustments without departing from the spirit and scope of the present disclosure. Accordingly, the scope of protection of the present invention can be defined by the claims.

What is claimed is:

1. An immersion cooling system, including:
an enclosure, including an inner space;
a heating part, disposed in the inner space; and
a working fluid, filled in the inner space, and having thermal contact with the heating part, wherein the waste heat generated by the heating part is transmitted by the working fluid, to the outside of the enclosure;
wherein, a composition of the working fluid includes a non-conductive coolant and a plurality of modified boron nitride microparticles, and a molecular structure of the modified boron nitride microparticles includes an organic functional group, wherein the non-conductive coolant and the modified boron nitride microparticles are dissolved in the working fluid.

2. The immersion cooling system according to claim 1, wherein the non-conductive coolant includes an unsaturated fluoro-olefin compound, unsaturated fluoro-olefin hydroxyl compound, or unsaturated fluorinated olefin compound.

3. The immersion cooling system according to claim 1, wherein the immersion cooling system further includes a passive convection heat transfer mode and a forced convection heat transfer mode, wherein in the passive convection heat transfer mode, the working fluid does not undergo a forced convection during heat transfer operation; or, in the forced convection heat transfer mode, the working fluid transfers heat through the forced convection during the heat transfer operation.

4. The immersion cooling system according to claim 3, wherein each of the modified boron nitride microparticles includes an atomic arrangement of a hexagonal boron nitride lattice or a cubic boron nitride lattice, wherein in the passive convection heat transfer mode and the forced convection heat transfer mode, a lattice vibration effect of the modified boron nitride microparticles in the working fluid, enhances the working fluid to exhibit a higher heat transfer efficiency than the non-conductive coolant.

5. The immersion cooling system according to claim 1, wherein the modified boron nitride microparticles are not in a suspended status in the working fluid.

6. The immersion cooling system according to claim 1, wherein the particle size of the modified boron nitride microparticles is in the preferred range of 0.01 μm to 5 μm.

7. The immersion cooling system according to claim 1, wherein the preferred concentration of the modified boron nitride microparticles in the working fluid ranges from 100 PPM to 10000 PPM.

8. The immersion cooling system according to claim 1, wherein a specific gravity of the modified boron nitride microparticles in the working fluid is fundamentally equivalent to a specific gravity of the non-conductive coolant.

9. The immersion cooling system according to claim 1, wherein the molecular structure of the modified boron nitride microparticles includes an organic functional group or a hydroxyl group.

10. A working fluid used in an immersion cooling system, including:
an unsaturated fluoro-olefin compound, an unsaturated fluoro-olefin hydroxyl compound, or an unsaturated fluorinated olefin compound, or a combination thereof; and
a plurality of modified boron nitride microparticles, dissolved with the unsaturated fluoro-olefin compound, unsaturated fluoro-olefin hydroxyl compound, or unsaturated fluorinated olefin compound in the working fluid, the modified boron nitride microparticles including an atomic arrangement of a hexagonal boron nitride lattice or a cubic boron nitride lattice, the working fluid exhibiting an enhanced heat transfer efficiency due to a lattice vibration effect of the modified boron nitride microparticles, and further due to a combination of the modified boron nitride microparticles and the unsaturated fluoro-olefin compound, unsaturated fluoro-olefin hydroxyl compound, or unsaturated fluorinated olefin compound.
